(19) United States
(12) Patent Application Publication
(10) Pub. No.: US 2023/0120716 A1
(43) Pub. Date: Apr. 20, 2023

(54) APPARATUS FOR TREATING SUBSTRATE AND METHOD FOR OPERATING THEREOF

(71) Applicant: SEMES CO., LTD., Cheonan-si (KR)

(72) Inventors: Yoon Seok CHOI, Suwon-si (KR); Yun Sang KIM, Seongnam-si (KR); Soon-Cheon CHO, Pyeongtaek-si (KR); Sang Jeong LEE, Hwaseong-si (KR); Jong Won PARK, Hwaseong-si (KR); Hyun Woo JO, Hwaseong-si (KR)

(73) Assignee: SEMES CO., LTD., Cheonan-si (KR)

(21) Appl. No.: 17/967,172

(22) Filed: Oct. 17, 2022

(30) Foreign Application Priority Data
Oct. 20, 2021 (KR) 10-2021-0139988

(51) Int. Cl. H01J 37/32; H05B 6/70

(52) U.S. Cl. CPC H01J 37/32275; H01J 37/32229; H05B 6/707

(57) ABSTRACT

The inventive concept provides a substrate treating apparatus. The substrate treating apparatus includes a plurality of process chambers for performing a first process using a microwave energy; one microwave generator for generating a microwave; a wave guide connecting to each of the plurality of process chambers and the microwave generator; and a microwave path changing member provided at a microwave transfer path of the wave guide and changing the microwave transfer path of one chosen chamber among the plurality of process chambers.

### CROSS-REFERENCE TO RELATED APPLICATIONS

A claim for priority under 35 U.S.C. § 119 is made to Korean Patent Application No. 10-2021-0139988 filed on Oct. 20, 2021, in the Korean Intellectual Property Office, the entire contents of which are hereby incorporated by reference.

### BACKGROUND

Embodiments of the inventive concept described herein relate to a substrate treating apparatus and an operating method of the substrate treating apparatus.

In a process of heating a substrate or a process of generating a plasma using a process gas among a substrate treating process, a microwave may be used as energy. The microwave is generated by a microwave generator. Since the substrate can be heated in a short time if a high-power microwave is used, there have been attempts to heat the substrate using the microwave.

However, a high-power microwave generator of 10 kW or above for generating the high-power microwave takes up a lot of space due to its large volume, and it is also difficult to apply because it is expensive.

### SUMMARY

Embodiments of the inventive concept provide a substrate treating apparatus which includes a high-power microwave generator of 10 kW or above for generating a microwave and which reduces a footprint.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a plurality of process chambers for performing a first process using a microwave energy; one microwave generator for generating a microwave; a wave guide connecting to each of the plurality of process chambers and the microwave generator; and a microwave path changing member provided at a microwave transfer path of the wave guide and changing the microwave transfer path of one chosen chamber among the plurality of process chambers.

In an embodiment, the microwave generator is a high output microwave generator of 10 kW or above.

In an embodiment, a first process is a process of heating a substrate, and the heating is performed by the microwave.

In an embodiment, the heating is performed by exposing the substrate to the microwave for several microseconds to several seconds.

In an embodiment, the first process performs a process of treating the substrate with a plasma, and the plasma is generated by a process gas by the microwave.

In an embodiment, the wave guide includes: a main wave guide; and a plurality of branch wave guides branching from the main wave guide and transferring the microwave corresponding to each of the plurality of process chambers, and wherein the microwave path changing member is provided in a plurality, provided at each inlet of the plurality of branch wave guides, and which opens and closes an inlet of the branch wave guide.

In an embodiment, the microwave path changing member includes: a plate in a metal material; and a driving portion which changes a posture of the plate to a first posture and a second posture.

In an embodiment, the substrate treating apparatus further includes a controller, and wherein the controller controls the microwave path changing member to transfer the microwave to a process chamber at which the first process is performed among the plurality of process chambers.

In an embodiment, the plurality of process chambers perform the first process at different times.

In an embodiment, the microwave path changing member is provided in a material which is the same material as the wave guide.

The inventive concept provides an operating method for a substrate treating apparatus, the substrate treating apparatus including: a plurality of process chambers for performing a first process using a microwave energy; one microwave generator for generating a microwave; a wave guide connecting to each of the plurality of process chambers and the microwave generator; and a microwave path changing member provided at a microwave transfer path of the wave guide and changing the microwave transfer path of one chosen chamber among the plurality of process chambers. The operating method includes performing the first process at different times by the plurality of the process chambers, and transferring the microwave to the one chosen process chamber from any one process chamber among the plurality of process chambers while the first process is being performed.

In an embodiment, the first process is a process of heating the substrate, and the heating is performed by the microwave.

In an embodiment, the heating is performed by exposing the substrate to the microwave for several microseconds to several seconds.

In an embodiment, the first process performs a process of treating the substrate with a plasma, and the plasma is generated by a process gas by the microwave.

In an embodiment, the microwave generator is a high-output microwave generator of 10 kW or above.

In an embodiment, the wave guide includes: a main wave guide; and a plurality of branch wave guides branching from the main wave guide and transferring the microwave corresponding to each of the plurality of process chambers, and wherein the microwave path changing member is provided in a plurality, provided at each inlet of the plurality of branch wave guides, and which opens and closes an inlet of the branch wave guide.

In an embodiment, the microwave path changing member includes: a plate in a metal material; and a driving portion which changes a posture of the plate to a first posture or a second posture, and wherein the first posture is a position adjusted to transfer the microwave to a corresponding process chamber, and the second posture is a position adjusted to let the microwave pass through.

The inventive concept provides a substrate treating apparatus. The substrate treating apparatus includes a plurality of process chambers for performing a first process using a microwave energy; one microwave generator for generating a microwave; a wave guide including a main wave guide, a plurality of branch wave guides branching from the main wave guide and transferring the microwave corresponding to each of the plurality of process chambers, and connecting each of the plurality of process chambers and the microwave generator; a microwave path changing member provided in a plurality, provided at each inlet of the plurality of branch wave guides, and which opens and closes an inlet of the branch wave guide so change a microwave transfer path of one chosen chamber among the plurality of process chambers; and a controller, and wherein the first process is a process of treating a substrate using the microwave or a process of treating the substrate using a plasma generated from a process gas by the microwave, and wherein the microwave generator is a high output microwave generator of 10 kW or above, and the controller controls the microwave generator and the microwave path changing member so the plurality of process chambers perform the first process at different times, and so the microwave is transmitted to the one chosen chamber from any one chamber among the plurality of process chamber while the first process is being performed.

According to an embodiment of the inventive concept, a high-power microwave generator of 10 kW or above for generating a microwave may be included while reducing a footprint.

According to an embodiment of the inventive concept, a microwave may be supplied to a plurality of process chambers by one microwave generator, thus a using efficiency of the microwave generator is high.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus according to an embodiment of the inventive concept.

FIG. 2 illustrates the substrate treating apparatus according to an embodiment of the inventive concept.

FIG. 3 to FIG. 6 illustrate an operating method of the substrate treating apparatus according to an embodiment of the inventive concept.

FIG. 3 describes a state in which a microwave is transmitted to a first process chamber PM1.

FIG. 4 describes a state in which a microwave is transmitted to a second process chamber PM2.

FIG. 5 describes a state in which a microwave is transmitted to a third process chamber PM3.

FIG. 6 describes a state in which a microwave is transmitted to a fourth process chamber PM4.

FIG. 7 is a flowchart illustrating the operating method of the substrate treating apparatus according to an embodiment of the inventive concept over time.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

In the specification, the singular forms include plural forms unless particularly mentioned. Also, the shapes or sizes of elements in a figure may be exaggerated for a clearer illustration.

In an embodiment of the inventive concept, a substrate treating apparatus for etching a substrate using a plasma will be described. However, the technical features of the inventive concept are not limited thereto, and may be applied to various types of apparatuses which treat the substrate W using the plasma. However, the inventive concept is not limited thereto, and may be applied to various types of apparatuses for plasma-treating a substrate placed on the top.

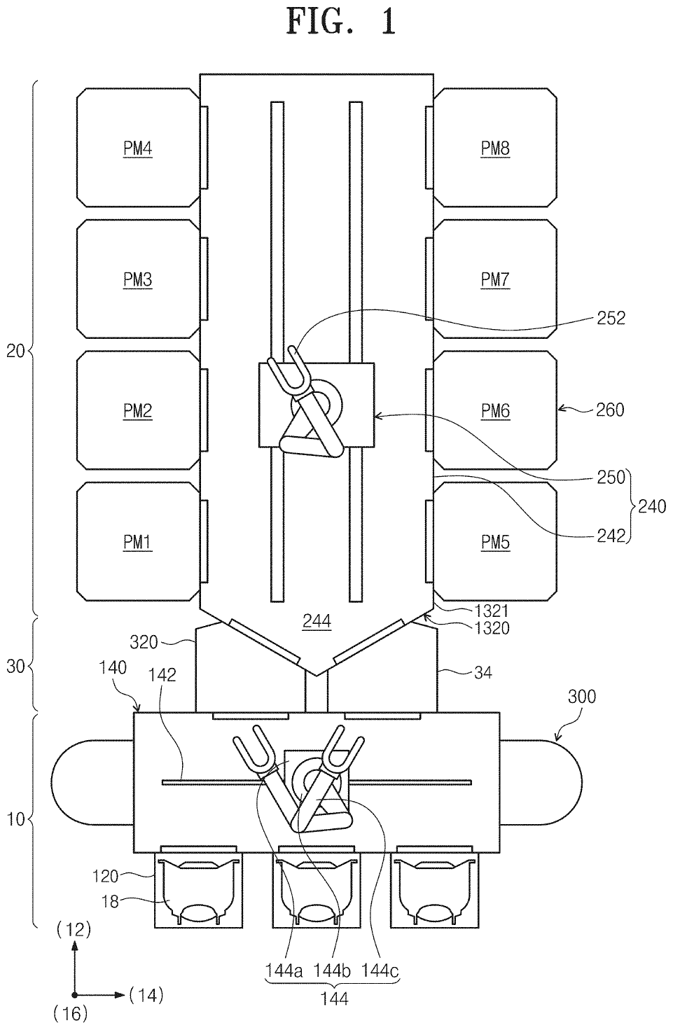

FIG. 1 illustrates a substrate treating apparatus according to an embodiment of the inventive concept.

See FIG. 1. A substrate treating facility 1 includes an index module 10, a loading module 30, and a process module 20.

The index module 10 has a load port 120, a transfer frame 140, and a buffer unit 300. The load port 120, the transfer frame 140, and the process module 20 are sequentially arranged in a direction. Hereinafter, a direction in which the load port 120, the transfer frame 140, the loading module 30, and the process module 20 are arranged is referred to as a first direction 12, a direction perpendicular to the first direction 12 is referred to as a second direction 14, and a direction which is perpendicular to a plane including the first direction 12 and the second direction 14 is referred to as a third direction 16.

A carrier 18 in which a plurality of substrates W are stored is mounted on the load port 120. A plurality of load ports 120 are provided and are arranged along the second direction 14. FIG. 1 illustrates that three load ports 120 are provided. However, the number of load ports 120 may increase or decrease according to conditions such as a process efficiency of the process module 20 and a foot print. A slot (not shown) provided to support an edge of a substrate is formed in the carrier 18. A plurality of slots are provided along the third direction 16, and the substrate is positioned in the carrier to be stacked while being spaced apart from each other along the third direction 16. A front opening unified pod (FOUP) may be used as the carrier 18.

The transfer frame 140 transfers the substrate W between the carrier 18 mounted on the load port 120, the buffer unit 300, and the loading module 30. An index rail 142 and an index robot 144 are provided in the transfer frame 140. A lengthwise direction of the index rail 142 is provided parallel to the second direction 14. The index robot 144 is installed on the index rail 142 and moves linearly in the second direction 14 along the index rail 142. The index robot 144 has a base 144a, a body 144b, and an index arm 144c. The base 144a is installed to be movable along the index rail 142. The body 144b is coupled to the base 144a. The body 144b is provided to be movable along the third direction 16 on the base 144a. In addition, the body 144b is provided to be rotatable on the base 144a. The index arm 144c is coupled to the body 144b and is provided to be forwardly and backwardly movable with respect to the body 144b. A plurality of index arms 144c are provided to be individually driven. The index arms 144c are disposed to be stacked while being spaced apart from each other in the third direction 16. Some of the index arms 144c may be used to transfer the substrate W from the process module 20 to the carrier 18, and others may be used to transfer the substrate W from the carrier 18 to the process module 20. This may prevent particles generated from the substrate W before a process treatment from being attached to the substrate W after the process treatment in a process of taking in and taking out the substrate W by the index robot 144.

The buffer unit 300 temporarily stores a substrate W treated at a process module 20. In the buffer unit 300, process by-products remaining on the substrate W are removed. A removal of process by-products from the buffer unit 300 is performed by pressurizing or depressurizing an inside of the buffer unit 300. A plurality of buffer units 300 may be provided. For example, two buffer units 300 may be provided. The two buffer units 300 may be provided on both sides of the transfer frame 140 and may be positioned to face each other with the transfer frame 140 interposed therebetween. Selectively, only one buffer unit 300 may be provided on a side of the transfer frame 140.

The loading module 30 is disposed between the transfer frame 140 and the transfer unit 242. The loading module 30 provides a space in which the substrate W stays before the substrate W is transferred between the transfer unit 242 and the transfer frame 140. The loading module 30 includes a plurality of load lock chambers 32 and 34. Each of the load lock chambers 32 and 34 is provided to be changeable between a vacuum atmosphere and an atmospheric pressure atmosphere.

In the load lock chambers 32 and 34, the substrate W transferred between the index module 10 and the process module 20 temporarily stays. If the substrate W is taken into the load lock chambers 32 and 34, the inner space is sealed with respect to each of the index module 10 and the process module 20. After that, an inner space of the load lock chamber 32 is changed into the atmospheric pressure atmosphere or the vacuum atmosphere, and is opened to any one of the index module 10 or the process module 20 while being sealed to the other.

For example, if the substrate is transferred from the index module 10 to the process module 20, the load lock chambers 32 and 34 can be opened to the process module 20 while keeping an inner space closed with respect to the index module 10 after changing the inner space from the atmospheric pressure atmosphere to the vacuum atmosphere.

Unlike this, if the substrate is transferred from the process module 20 to the index module 10, the load lock chambers 32 and 34 can be opened to the index module 10 with the inner space closed with respect to the process module 20 after changing from the vacuum atmosphere to the atmospheric pressure atmosphere.

Selectively, one of the load lock chambers 32 and 34 may be used to transfer the substrate from the index module 10 to the process module 20, and the other may be used to transfer the substrate from the process module 20 to the index module 10.

The process module 20 includes a transfer unit 242 and a plurality of process chambers 260.

The transfer unit 242 transfers the substrate W between the load lock chambers 32 and 34 and a plurality of process chambers 260. The transfer unit 242 may be provided in a hexagonal shape when viewed from above. Optionally, the transfer unit 242 may be provided in a rectangular shape or a pentagonal shape. The load lock chambers 32 and 34 and the plurality of process chambers 260 are positioned around the transfer unit 242. A transfer robot 250 is provided in the transfer unit 242. The transfer robot 250 may be positioned in a central portion of the transfer unit 242. The transfer robot 250 may have a hand 252 that may move in a horizontal direction and a vertical direction and may move forwardly, backwardly, or rotate on a horizontal plane. Each hand 252 may be independently driven, and the substrate W may be mounted on the hand 252 in a horizontal state.

A plurality of process chambers 260 are provided. In one embodiment, regarding the process chamber 260, four PM1, PM2, PM3, PM4 are disposed along the first direction 12 at a side of the transfer unit 242, and four PM5, PM6, PM7, PM8 are disposed along the first direction 12 at the other side of the transfer unit 242. In an embodiment, the process chamber 260 is an apparatus for treating the substrate with microwaves. In the process chamber 260, the substrate W may be etched, deposited, or heat treated.

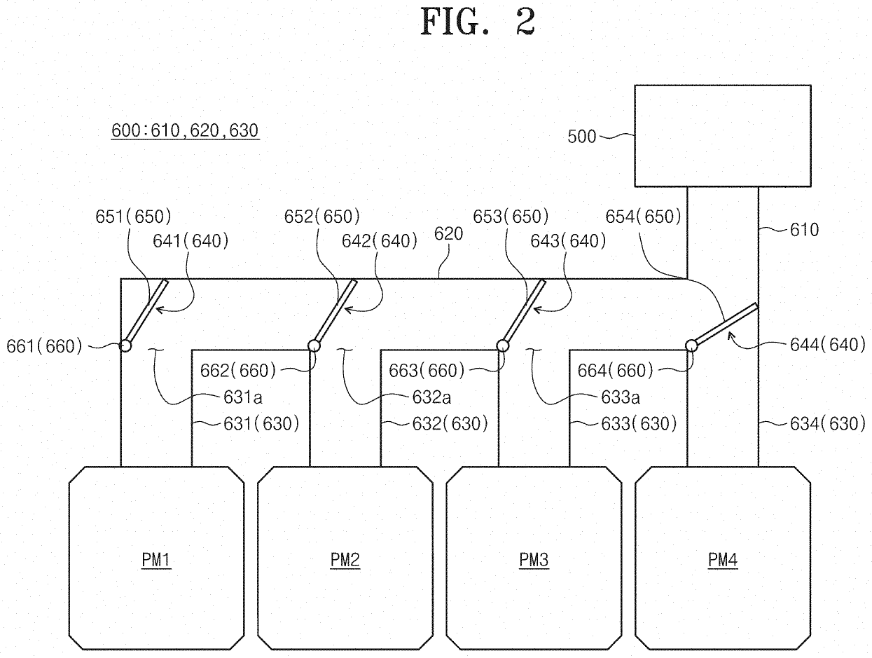

FIG. 2 illustrates the substrate treating apparatus according to an embodiment of the inventive concept. The substrate treating apparatus includes a microwave generator 500, a waveguide 600, and a plurality of process chambers. Although four process chambers PM1, PM2, PM3, and PM4 are provided as embodiments, the number of process chambers may be appropriately set in accordance with a design layout.

The microwave generator 500 generates microwaves. The microwave generator 500 is a high-power microwave generator of 10 kW or above. The microwave generator 500 outputs a high-power pulse.

The waveguide 600 connects the plurality of process chambers and the microwave generator 500. The waveguide 600 includes main waveguides 610 and 620 and a branch waveguide 630. The branch waveguide 630 is a waveguide branched from the waveguide 620. The branch waveguide 630 is provided in a number corresponding to the process chambers. The waveguide 600 forms a guide path for guiding a microwave generated from the microwave generator 500 to the process chamber. A side of the main waveguide 610 and 620 is connected to the microwave generator 500, and is connected to a plurality of branch waveguides 630 while extending. A plurality of branch waveguides 630 are provided, and each branch waveguide 630 is connected to each process chamber. In an embodiment, a side of a first branch waveguide 631 is connected to the main waveguide 610 and 620 and the other side thereof is connected to a first process chamber PM1. A side of the second waveguide 632 is connected to the main waveguide 610 and 620 and the other side thereof is connected to a second process chamber PM2. A side of the third waveguide 633 is connected to the main waveguide 610 and 620 and the other side thereof is connected to a third process chamber PM3. A side of the fourth waveguide 634 is connected to the main waveguide 610 and 620 and the other side thereof is connected to a fourth process chamber PM4.

A microwave path changing member 640 is provided inside the waveguide 600. A plurality of microwave path changing members 640 are provided. The microwave path changing member 640 is provided at an inlet of each branch waveguide 630. The microwave path changing member 640 opens and closes the inlet of each branch waveguide 630. In an embodiment, the microwave path changing member 640 includes a plate portion 650 and a driving portion 660. The plate portion 650 may be provided as a plate-shaped member. The plate portion 650 is a metal material capable of transmitting a microwave. The plate portion 650 may be formed of the same material as the waveguide 600. A side of the plate portion 650 is connected to the driving portion 660 to be tilted between a first posture and a second posture. The driving portion 660 may be provided as a motor. The driving portion 660 is connected to a side of the plate portion 650 so that the plate portion 650 may be selectively changed to the first posture or the second posture. The first posture is a position adjusted to transfer the microwave to a corresponding process chamber, and the second posture is a position adjusted to let the microwave pass through. The first posture and the second posture may vary depending on an arrangement relationship between the microwave path changing member 640, the main waveguide 610 and 620, and the branch waveguide 630.

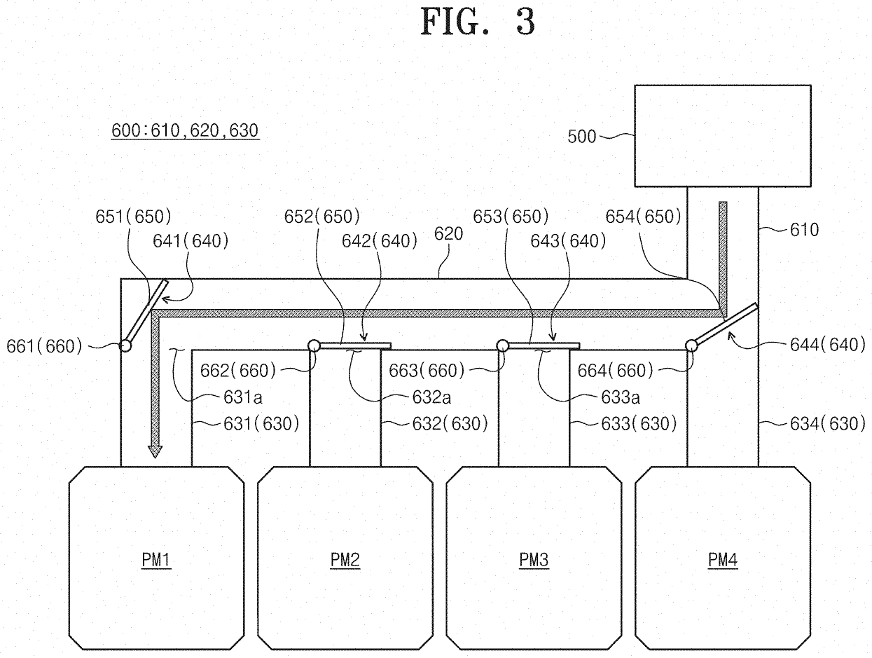

Hereinafter, an operating method of the substrate treating apparatus according to an embodiment of the inventive concept will be described with reference to FIG. 3 to FIG. 6.

FIG. 3 describes a state in which a microwave is transmitted to the first process chamber PM1. In an embodiment, a first microwave path changing member 641 may be installed at a part at which the first branch waveguide 631 and the main waveguide 620 are connected, that is, an inlet 631a of the first branch waveguide 631. The first microwave path changing member 641 may open and close the inlet 631a. If the first microwave path changing member 641 is controlled to the second posture to close the inlet 631a, microwave is not transmitted to the first process chamber PM1. Even if the first microwave path changing member 641 is controlled to the first posture to open the inlet 631a, the second microwave path changing member 642, the third microwave path changing member 643, and the fourth microwave path changing member 644 to be described later must be controlled to the second posture and controlled in direction to close each inlet.

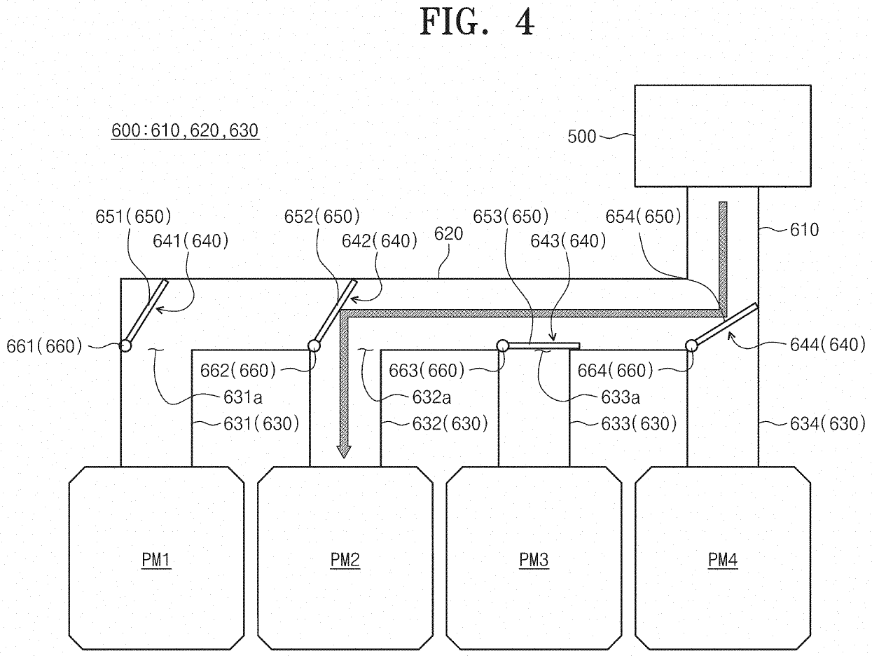

FIG. 4 describes a state in which the microwave is transmitted to the second process chamber PM2. A second microwave path changing member 642 may be installed at a part at which the second waveguide 632 and the main waveguide 620 are connected, that is, an inlet 632a of the second waveguide 632. The second microwave path changing member 642 may open and close the inlet 632a. If the second microwave path changing member 642 is controlled to the second posture to close the inlet 642a, the microwave is not transmitted to the second process chamber PM2. On the other hand, if the second microwave path changing member 642 is controlled to the first posture to open the inlet 642a, the microwave may be transmitted to the second process chamber PM2, but a path to the first process chamber PM1 is closed so that the microwave is not transmitted to the first process chamber PM1. Even if the second microwave path changing member 642 is controlled to the second posture to open the inlet 632a, each of the third microwave path changing member 643 and the fourth microwave path changing member 644 to be described later must be controlled to the second posture and controlled in a direction to close each inlet in order to transfer the microwave to the second process chamber PM2.

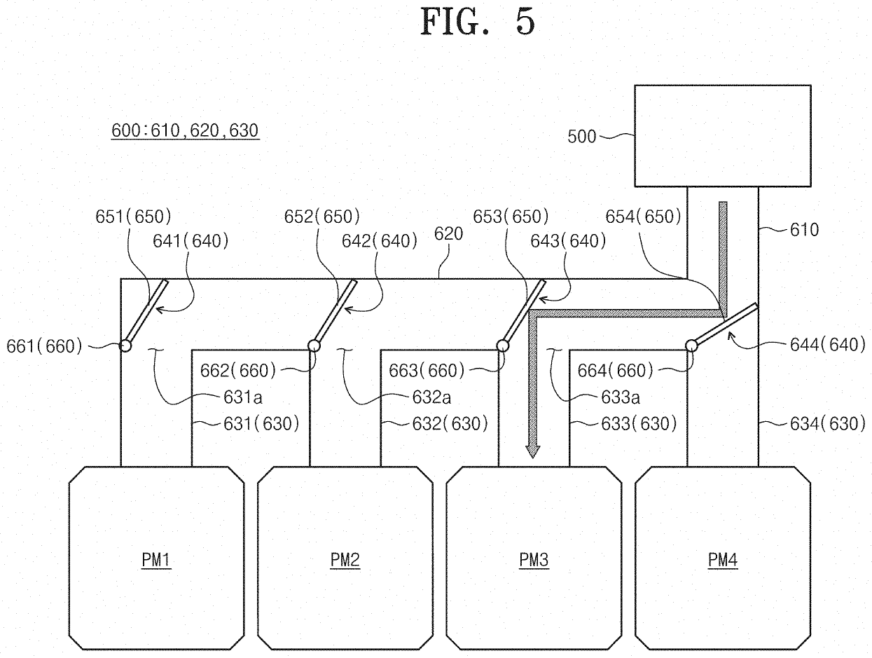

FIG. 5 describes a state in which a microwave is transmitted to the third process chamber PM3. A third microwave path changing member 643 may be installed at a part where the third waveguide 633 and the main waveguide 620 are connected, that is, an inlet 633a of the third waveguide 633. The third microwave path changing member 643 may open and close the inlet 633a. If the third microwave path changing member 643 is controlled to the second posture to close the inlet 643a, the microwave is not transmitted to the third process chamber PM3. On the other hand, if the third microwave path changing member 643 is controlled to the first posture to open the inlet 643a, the microwave may be transmitted to the third process chamber PM3, but a path to the first process chamber PM1 and the second process chamber PM2 is closed so to the microwave is not transmitted to the first process chamber PM1 and the second process chamber PM2. Even if the third microwave path changing member 643 is controlled to the second posture to open the inlet 633a, the fourth microwave path changing member 644 to be described later must be controlled to the second posture and controlled in a direction to close each inlet in order to transfer the microwave to the third process chamber PM3.

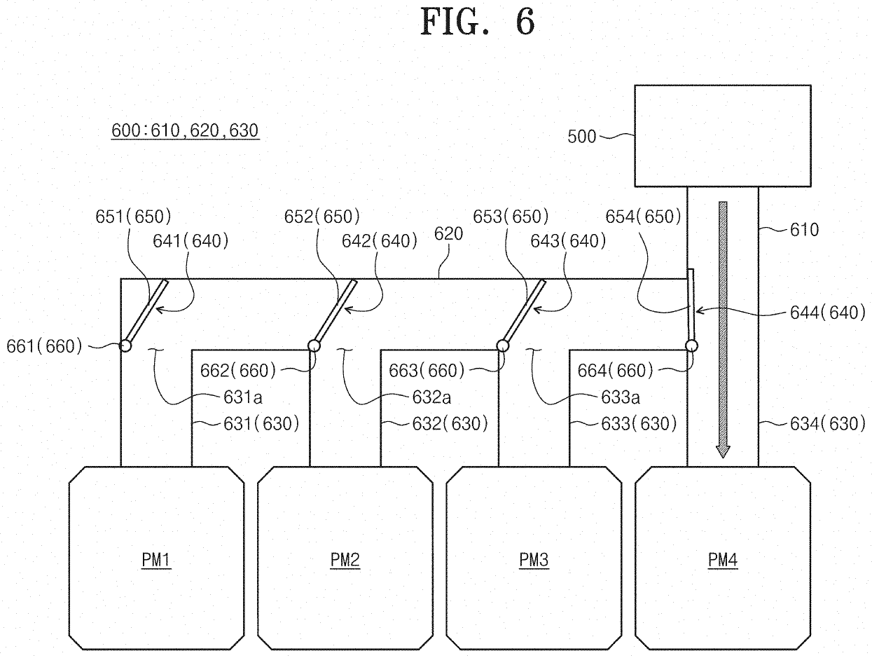

FIG. 6 describes a state in which the microwave is transmitted to the fourth process chamber PM4. A fourth microwave path changing member 644 may be installed at a part where the fourth waveguide 634 and the main waveguide 620 are connected, that is, an inlet 634a of the fourth waveguide 634. The fourth microwave path changing member 644 may open and close the inlet 634a. If the fourth microwave path changing member 644 is controlled to the second posture to close the inlet 643a, the microwave is not transmitted to the fourth process chamber PM4. On the other hand, if the fourth microwave path changing member 644 is controlled to the first posture to open the inlet 644a, the microwave may be transmitted to the fourth process chamber PM4, but a path to the first process chamber PM1, the second process chamber PM2, and the third process chamber PM3 is closed and so the microwave is not transmitted to the first process chamber PM1, the second process chamber PM2, and the third process chamber PM3.

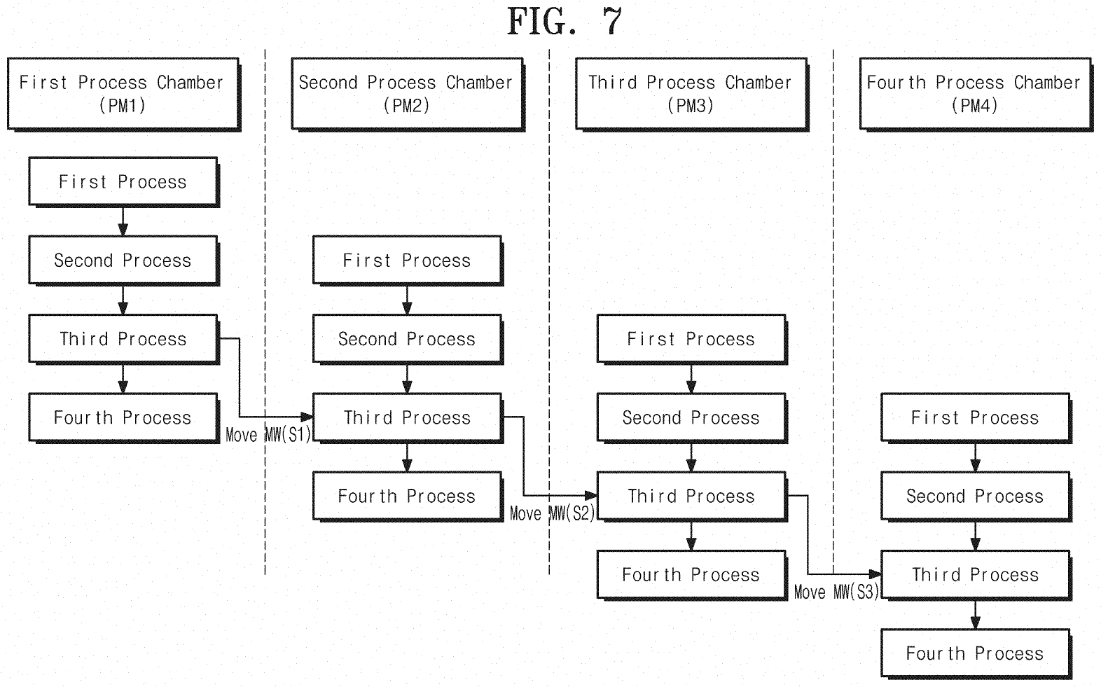

FIG. 7 is a flowchart illustrating an operating method of the substrate treating apparatus according to an embodiment of the inventive concept over time.

According to an embodiment, the substrate treating apparatus is controlled by a controller (not shown). The controller (not shown) may control an overall operation of the substrate treating apparatus 1000. The controller (not shown) may include a central processing unit (CPU), a read only memory (ROM), and a random access memory (RAM). The CPU executes desired processes such as an etching, a film formation, and a heat treatment according to various recipes stored in storage areas.

In an embodiment, a first process may be a modification process of a film material. The modification process may be a process such as supplying a chemical to the substrate or generating a plasma from a process gas and treating. In an embodiment, an energy for generating the process gas into the plasma may be a microwave. The microwave may be generated by a microwave generator 500 and transmitted to a selected process chamber 260 through the waveguide 600. Although not described in the drawings, the microwave may be used in the first process. A second process may be a purge process. A third process may be a heating process. In the heating process, an energy for heating the substrate W may be a microwave. The microwave may be generated by the microwave generator 500 and transmitted to a selected process chamber 260 through the waveguide 600. A fourth process may be a purge process. Compared to the third process, the first process, the second process, and the fourth process may be performed for a relatively long time. In an embodiment, the third process, which is a heating process, is performed for several microseconds to several seconds, and can be performed by exposing the substrate W to the microwave for several microseconds to several seconds.

For convenience of description, a case in which the microwave is used in a third process (corresponding to the first process in the claims) will be described. The controller (not shown) controls the microwave path changing member 640. The controller (not shown) controls the microwave to be transmitted to the first process chamber PM1 which has performed the first process and the second process. Other processes are performed in the second process chamber PM2, the third process chamber PM3, and the fourth process chamber PM4 while the third process is performed in the first process chamber PM1. If the third process is completed in the first process chamber PM1, the controller (not shown) controls the microwave path changing member 640 to control the microwave to be transmitted to the second process chamber PM2 S1. In the case of using the microwave to heat the substrate W, while the substrate W is heated the microwave generator 500 is maintained in a power-on state, and while the substrate W is cooled, or for example if a process such as the above described first process, second process, fourth process is performed, the microgenerator 500 is maintained in a power-off state for a substantially long time. According to an embodiment of the inventive concept, one microwave generator 500 may supply the microwave to a plurality of process chambers such as the first process chamber to the fourth process chamber PM1, PM2, PM3, and PM4, thereby increasing a use efficiency of the microwave generator 500.

Other processes are performed in the first process chamber PM1, the third process chamber PM3, and the fourth process chamber PM4 while the third process is performed in the second process chamber PM2. If the third process is completed in the second process chamber PM2, the controller (not shown) controls the microwave path changing member 640 to control the microwave to be transmitted to the third process chamber PM3 S2.

Similarly, while the third process is performed in the third process chamber PM3, other processes are performed in the first process chamber PM1, the second process chamber PM2, and the fourth process chamber PM4. If the third process is completed in the third process chamber PM3, the controller (not shown) controls the microwave path changing member 640 to control the microwave to be transmitted to the fourth process chamber PM4 S3.

In addition, while the third process is performed in the fourth process chamber PM4, other processes are performed in the first process chamber PM1, the second process chamber PM2, and the third process chamber PM3. If the third process is completed in the fourth process chamber PM4, the controller (not shown) controls the microwave path changing member 640 to control the microwave to be transferred to the first process chamber PM4. Alternatively, in an embodiment not shown, a fifth process chamber PM5 is further connected with the waveguide, and the microwave is transmitted to the fifth process chamber PM5 (see FIG. 1).

As described above, each of the process chambers PM1, PM2, PM3, and PM4 performs the third process at different times. In addition, while changing the path by the microwave path changing member 640 provided inside the waveguide 600, the microwave can be applied to each process chamber PM1, PM2, PM3, PM4 to perform a process using the microwave.

According to the above-described embodiment, since the microwave can be supplied to multiple process chambers using one microwave generator 500, a use efficiency of the microwave generator 500 is high, and a plurality of microwave generators do not need to be provided corresponding to the plurality of process chambers, so there may be a conservation from using the expensive microwave generators and a footprint can be reduced.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a plurality of process chambers for performing a first process using a microwave energy;
one microwave generator for generating a microwave;
a wave guide connecting to each of the plurality of process chambers and the microwave generator; and
a microwave path changing member provided at a microwave transfer path of the wave guide and changing the microwave transfer path of one chosen chamber among the plurality of process chambers.

2. The substrate treating apparatus of claim 1, wherein the microwave generator is a high output microwave generator of 10 kW or above.

3. The substrate treating apparatus of claim 1, wherein a first process is a process of heating a substrate, and the heating is performed by the microwave.

4. The substrate treating apparatus of claim 3, wherein the heating is performed by exposing the substrate to the microwave for several microseconds to several seconds.

5. The substrate treating apparatus of claim 1, wherein the first process performs a process of treating the substrate with a plasma, and the plasma is generated by a process gas by the microwave.

6. The substrate treating apparatus of claim 1, wherein the wave guide comprises:
a main wave guide; and
a plurality of branch wave guides branching from the main wave guide and transferring the microwave corresponding to each of the plurality of process chambers, and
wherein the microwave path changing member is provided in a plurality, provided at each inlet of the plurality of branch wave guides, and which opens and closes an inlet of the branch wave guide.

7. The substrate treating apparatus of claim 1, wherein the microwave path changing member comprises:
a plate in a metal material; and
a driving portion which changes a posture of the plate to a first posture and a second posture.

8. The substrate treating apparatus of claim 1 further comprising a controller, and
wherein the controller controls the microwave path changing member to transfer the microwave to a process chamber at which the first process is performed among the plurality of process chambers.

9. The substrate treating apparatus of claim 1, wherein the plurality of process chambers perform the first process at different times.

10. The substrate treating apparatus of claim 1, wherein the microwave path changing member is provided in a material which is the same material as the wave guide.

11.-17. (canceled)

18. A substrate treating apparatus comprising:
a plurality of process chambers for performing a first process using a microwave energy;
one microwave generator for generating a microwave;
a wave guide including a main wave guide, a plurality of branch wave guides branching from the main wave guide and transferring the microwave corresponding to each of the plurality of process chambers, and connecting each of the plurality of process chambers and the microwave generator;
a microwave path changing member provided in a plurality, provided at each inlet of the plurality of branch wave guides, and which opens and closes an inlet of the branch wave guide so change a microwave transfer path of one chosen chamber among the plurality of process chambers; and
a controller, and
wherein the first process is a process of treating a substrate using the microwave or a process of treating the substrate using a plasma generated from a process gas by the microwave, and
the controller controls the microwave generator and the microwave path changing member so the plurality of process chambers perform the first process at different times, and so the microwave is transmitted to the one chosen chamber from any one chamber among the plurality of process chamber while the first process is being performed.

19. The substrate treating apparatus of claim 18,
wherein the microwave generator is a high output microwave generator of 10 kW or above.

20. The substrate treating apparatus of claim 19, wherein the microwave path changing member comprises:
a plate in a metal material; and
a driving portion which changes a posture of the plate to a first posture and a second posture.
